(19) United States
(12) Patent Application Publication
(10) Pub. No.: US 2024/0032292 A1
(43) Pub. Date: Jan. 25, 2024

(54) SEMICONDUCTOR MEMORY DEVICE AND MANUFACTURING METHOD OF SEMICONDUCTOR MEMORY DEVICE

(71) Applicant: SK hynix Inc., Icheon-si Gyeonggi-do (KR)

(72) Inventor: Jae Taek KIM, Icheon-si Gyeonggi-do (KR)

(73) Assignee: SK hynix Inc., Icheon-si Gyeonggi-do (KR)

(21) Appl. No.: 18/081,161

(22) Filed: Dec. 14, 2022

(30) Foreign Application Priority Data
Jul. 20, 2022 (KR) 10-2022-0089591

(51) Int. Cl. H10B 41/35; H10B 41/41; H10B 41/20; H10B 41/42; H10B 43/20; H10B 43/35; H10B 43/40; H01L 29/10; H01L 29/06; H01L 29/08; H01L 21/3105

(52) U.S. Cl. CPC H10B 41/35; H10B 41/41; H10B 41/20; H10B 41/42; H10B 43/20; H10B 43/35; H10B 43/40; H01L 29/1033; H01L 29/0649; H01L 29/0847; H01L 21/31053; H10B 99/22

(57) ABSTRACT

A semiconductor memory device includes: a substrate; a source stack structure and a source insulating layer disposed over the substrate to be spaced apart from each other; an isolation insulating layer disposed between the source stack structure and the source insulating layer; a first stack structure disposed over the source stack structure; a second stack structure disposed over the source insulating layer; a vertical structure penetrating the first stack structure and a portion of the source stack structure; and a lower contact penetrating the source insulating layer.

### CROSS-REFERENCE TO RELATED APPLICATION

The present application claims priority under 35 U.S.C. § 119(a) to Korean patent application number 10-2022-0089591, filed on Jul. 20, 2022, in the Korean Intellectual Property Office, the entire disclosure of which is incorporated herein by reference.

### BACKGROUND

### 1. Technical Field

The present disclosure generally relates to a semiconductor memory device and a manufacturing method of a semiconductor memory device, and more particularly, to a three-dimensional semiconductor memory device and a manufacturing method of a three-dimensional semiconductor memory device.

### 2. Related Art

Nonvolatile memory devices can electrically erase and program data and can retain stored data even when supply of power has been interrupted. Accordingly, the nonvolatile memory devices have recently been widely used in various fields.

Nonvolatile memory devices may be generally classified into a NAND-type nonvolatile memory device and a NOR-type nonvolatile memory device. The NAND-type nonvolatile memory device has an advantage of high integration, and the NOR-type nonvolatile memory device has an advantage of high speed.

Since the NAND-type nonvolatile memory device has a cell string structure including a plurality of memory cells, connected in series, the NAND-type nonvolatile memory device provides the advantage of high integration. Also, since the NAND-type nonvolatile memory device adopts an operation method of simultaneously changing data that are stored in the plurality of memory cells, a speed of updating data is remarkably high as compared with the NOR-type nonvolatile memory device. The NAND-type nonvolatile memory device is mainly used in a portable electronic device, which requires a mass storage device, such as a digital camera or a MP3 player because of high integration and high speed of updating data.

Studies for promoting and improving the advantages of the above-described NAND-type nonvolatile memory device have been conducted. As a part of these studies, NAND-type nonvolatile memory devices having three dimensional structures have been proposed.

### SUMMARY

In accordance with an embodiment of the present disclosure, there may be provided a semiconductor memory device including: a substrate; a source stack structure and a source insulating layer disposed over the substrate to be spaced apart from each other; an isolation insulating layer disposed between the source stack structure and the source insulating layer; a first stack structure disposed over the source stack structure; a second stack structure disposed over the source insulating layer; a vertical structure penetrating the first stack structure and a portion of the source stack structure; and a lower contact penetrating the source insulating layer.

In accordance with an embodiment of the present disclosure, there may be provided a semiconductor memory device including: a source stack structure and a source insulating layer disposed over a peripheral circuit to be spaced apart from each other; an isolation insulating layer disposed between the source insulating layer and the source stack structure; a first stack structure including a plurality of interlayer insulating layers and a plurality of conductive layers over the source stack structure; a slit partitioning the first stack structure, the slit extending into the source stack structure; and a lower contact penetrating the source insulating layer.

In accordance with an embodiment of the present disclosure, there may be provided a method of manufacturing a semiconductor memory device, the method including: forming a peripheral circuit structure on a substrate that includes a first region and a second region; forming a preliminary source stack structure over the peripheral circuit structure; forming an opening that penetrates the preliminary source stack structure, the opening overlapping with the second region of the substrate; forming a first insulating material along a sidewall of the opening; forming a second insulating material inside the opening; forming a lower contact that penetrates the second insulating material; forming a preliminary stack structure in which first material layers and second material layers are alternately stacked over the preliminary source stack structure; forming a vertical structure penetrating the preliminary stack structure and a portion of the preliminary source stack structure, the vertical structure overlapping with the first region of the substrate; and forming an upper contact that penetrates the preliminary stack structure and connects to the lower contact, the upper contact overlapping with the second region of the substrate.

In accordance with an embodiment of the present disclosure, there may be provided a method of manufacturing a semiconductor memory device, the method including: forming a preliminary source stack structure over a peripheral circuit structure, the preliminary source stack structure including a first source layer and a source sacrificial layer; forming an opening that penetrates the preliminary source stack structure; forming a first insulating material along a sidewall of the opening; forming a second insulating material inside the opening, which is opened by the first insulating material; forming a lower contact that penetrates the second insulating material; forming a preliminary stack structure in which first material layers and second material layers are alternately stacked over the preliminary source stack structure; forming a slit that penetrates the preliminary stack structure; and replacing the source sacrificial layer with a channel connection layer through the slit.

### BRIEF DESCRIPTION OF THE DRAWINGS

Various examples of embodiments will now be described more fully hereinafter with reference to the accompanying drawings; however, they may be embodied in different forms and should not be construed as limited to the embodiments set forth herein. Rather, these embodiments are provided so that this disclosure will be enabling to those skilled in the art.

In the drawing figures, dimensions may be exaggerated for clarity of illustration. It will be understood that when an element is referred to as being “between” two elements, it may be the only element between the two elements, or additional intervening elements may also be present. Like reference numerals refer to like elements throughout the drawings.

FIG. 1 is a block diagram schematically illustrating a semiconductor memory device in accordance with an embodiment of the present disclosure.

FIG. 2 is a plan view illustrating a memory block in accordance with an embodiment of the present disclosure.

FIGS. 3A and 3B are sectional views of semiconductor memory devices in accordance with embodiments of the present disclosure.

FIGS. 4A to 4C are sectional views illustrating a manufacturing method of a semiconductor memory device in accordance with an embodiment of the present disclosure.

FIGS. 5A, 5B, 6A, 6B, 7A, 7B, 8A, 8B, 9A, 9B, 10A, 10B, 11A, and 11B are sectional views illustrating a manufacturing method of a semiconductor memory device in accordance with an embodiment of the present disclosure.

FIG. 12 is a block diagram illustrating a configuration of a memory system in accordance with an embodiment of the present disclosure.

FIG. 13 is a block diagram illustrating a configuration of a computing system in accordance with an embodiment of the present disclosure.

### DETAILED DESCRIPTION

Specific structural and functional descriptions disclosed herein are merely illustrative for the purpose of describing embodiments according to the concept of the present disclosure. Embodiments according to the concept of the present disclosure can be implemented in various forms, and they should not be construed as being limited to the specific embodiments set forth herein.

It will be understood that, although the terms “first”, “second”, etc. may be used herein to describe various elements, these elements are not limited by these terms. These terms are used for distinguishing one element from another element and not to suggest a number or order of elements.

Embodiments provide a semiconductor memory device and a manufacturing method of a semiconductor memory device, which can improve operational reliability.

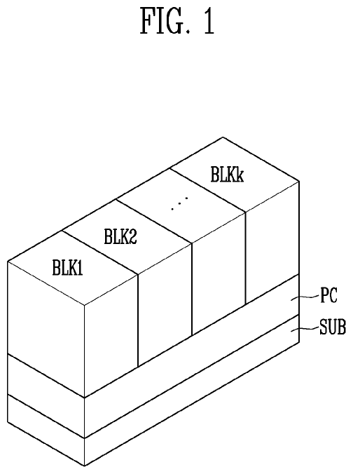

FIG. 1 is a block diagram schematically illustrating a semiconductor memory device in accordance with an embodiment of the present disclosure.

Referring to FIG. 1, the semiconductor memory device may include a peripheral circuit structure PC and memory blocks BLK1 to BLKk, which are disposed over a substrate SUB. The memory blocks BLK1 to BLKk may overlap with the peripheral circuit structure PC.

The substrate SUB may be a single crystalline semiconductor layer. For example, the substrate SUB may be a bulk silicon substrate, a silicon on insulator substrate, a germanium substrate, a germanium on insulator substrate, a silicon-germanium substrate, or an epitaxial thin film that is formed through a selective epitaxial growth process.

The peripheral circuit structure PC may include a row decoder, a column decoder, a page buffer, a control circuit, and the like, which constitute a circuit for controlling operations of the memory blocks BLK1 to BLKk. For example, the peripheral circuit structure PC may include an NMOS transistor, a PMOS transistor, a resistor, a capacitor, and the like, which are electrically connected to the memory blocks BLK1 to BLKk. The peripheral circuit structure PC may be disposed between the substrate SUB and the memory blocks BLK1 to BLKk.

Each of the memory blocks BLK1 to BLKk may include a source structure, bit lines, cell strings that are electrically connected to the source structure and the bit lines, word lines that are electrically connected to the cell strings, and select lines that are electrically connected to the cell strings. Each of the cell strings may include memory cells and select transistors, which are connected in series by a channel structure. Each of the select lines may be used as a gate electrode of a select transistor corresponding thereto, and each of the word lines may be used as a gate electrode of a memory cell corresponding thereto.

In another embodiment, the substrate SUB, the peripheral circuit structure PC, and the memory blocks BLK1 to BLKk may be stacked in the reverse order compared to the order shown in FIG. 1. The peripheral circuit structure PC may be disposed over the memory blocks BLK1 to BLKk.

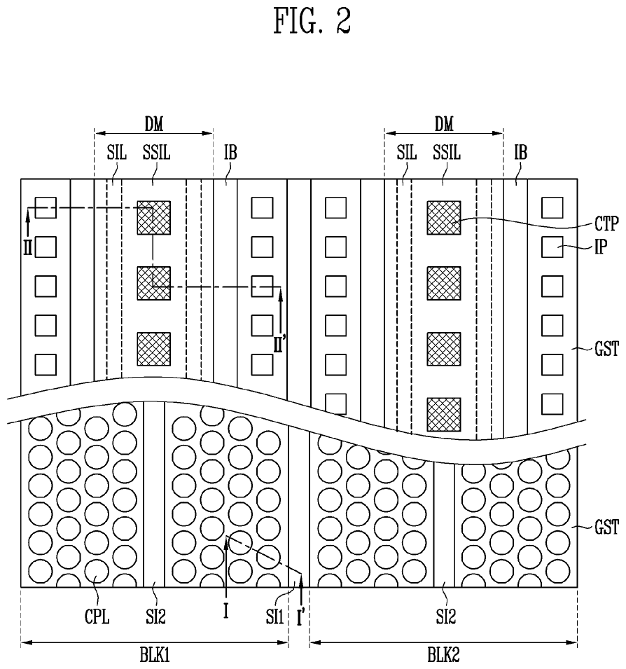

FIG. 2 is a plan view illustrating a memory block in accordance with an embodiment of the present disclosure. More specifically, FIG. 2 illustrates a layout of a first memory block and a second memory block, which are adjacent to each other.

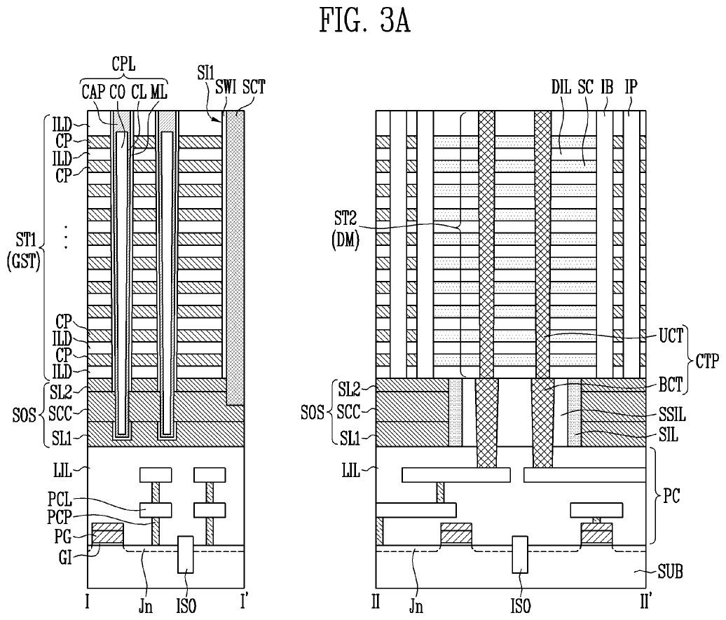

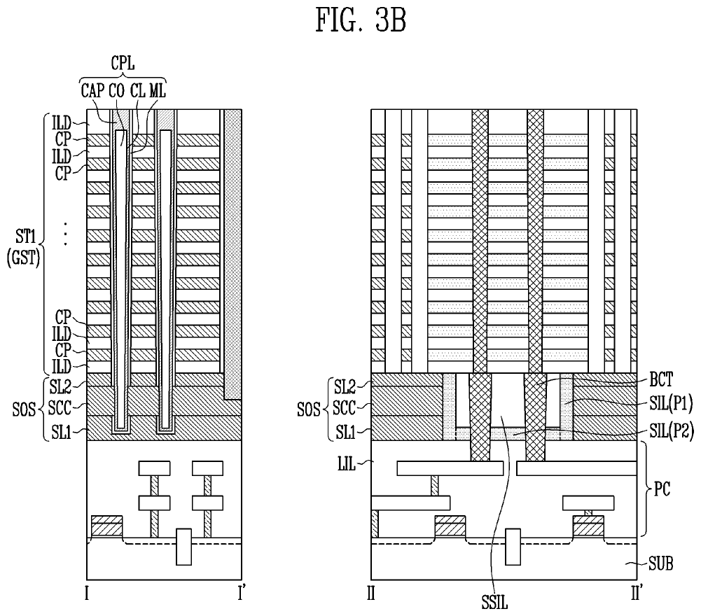

Referring to FIG. 2, each of memory blocks BLK1 and BLK2 may include a gate stack structure GST that is stacked over a source stack structure (SOS shown in FIG. 3A) and a dummy stack structure that is stacked over a source insulating layer SSIL. The gate stack structure GST may be isolated into the memory blocks BLK1 and BLK2 by a first slit SI1.

Each of the memory blocks BLK1 and BLK2 may be penetrated by vertical structures CPL and second slits SI2. The vertical structures CPL may penetrate a memory block corresponding thereto. The second slit SI2 may be disposed between the vertical structures CPL and may partition the gate stack structure GST. The source stack structure (SOS shown in FIG. 3A) may be used as an etch stop layer while the second slit SI2 is being formed.

The source insulating layer SSIL and an isolation insulating layer SIL may be disposed under the dummy stack structure DM. In other words, the dummy stack structure DM may overlap with the source insulating layer SSIL and the isolation insulating layer SIL. The dummy stack structure DM may be penetrated by a peripheral contact plug CTP. The peripheral contact plug CTP may extend into the source insulating layer SSIL, disposed under the dummy stack structure DM, while penetrating the dummy stack structure DM. In accordance with embodiments of the present disclosure, the isolation insulating layer SIL, in addition to the source insulating layer SSIL, may be disposed between the source stack structure (SOS shown in FIG. 3A) and under the gate stack structure GST and the peripheral contact plug CTP. Accordingly, in the embodiments of the present disclosure, a flow of current from the source stack structure (SOS shown in FIG. 3A) to the peripheral contact plug CTP may be blocked by the source insulating layer SSIL and the isolation insulating layer SIL, and deterioration of the operational reliability of the semiconductor memory device due to a leakage current from the source stack structure (SOS shown in FIG. 3A) to the peripheral contact plug CTP may be reduced.

The vertical structures CPL may be disposed between the first slit SI1 and the second slits SI2 that are adjacent thereto. The vertical structures CPL may extend into the source stack structure (SOS shown in FIG. 3A).

In order to improve the stability of a manufacturing process of the semiconductor memory device, support structures may be formed around the dummy stack structure DM. The support structures may be formed in various structures. More specifically, the support structures may include at least one of insulating pillars, insulating layers, and dummy channel pillars. FIG. 2 illustrates support structures including insulating pillars IP and insulating bars IB.

The insulating pillars IP and the insulating bars IB may be disposed to be adjacent to the source insulating layer SSIL and the isolation insulating layer SIL and may extend to penetrate the gate stack structure GST. Each of the insulating bars IB may be formed to be longer in a horizontal direction than each of the insulating pillars IP. An insulating material that fills the first slit SI1, the insulating pillars IP, and the insulating bars IB may block an etching material from being introduced toward a region in which the peripheral contact plug CTP is disposed while a process of manufacturing the semiconductor memory device is being performed.

FIGS. 3A and 3B are sectional views of semiconductor memory devices in accordance with embodiments of the present disclosure. Each of FIGS. 3A and 3B illustrates sectional views of the semiconductor memory device, taken along lines I-I′ and II-II′, shown in FIG. 2.

Referring to FIG. 3A, a source stack structure SOS and a peripheral contact plug CTP may be disposed over a peripheral circuit structure PC. The peripheral circuit structure PC may be disposed on a substrate SUB as described with reference to FIG. 1. According to the above-described structure, the peripheral circuit structure PC may be disposed between the substrate SUB and the source stack structure SOS. The substrate SUB may include well regions that are doped with an n-type or p-type impurity, and active regions that are isolated by an isolation layer ISO may be defined in the well regions of the substrate SUB. The isolation layer ISO may be formed of an insulating material.

The peripheral circuit structure PC may include peripheral gate electrodes PG, a gate insulating layer GI, junctions in that are used as a source region and a drain region, peripheral circuit lines PCL, lower contact plugs PCP, and a lower insulating layer LIL. The peripheral gate electrodes PG may be used as gate electrodes of NMOS and PMOS transistors. The gate insulating layer GI may be disposed between each of the peripheral gate electrodes PG and the substrate SUB. The junctions in may be regions that are defined by implanting an n-type or p-type impurity into the active region that overlap with each of the peripheral gate electrodes PG and may be disposed at both sides of each of the peripheral gate electrodes PG. The peripheral circuit lines PCL may be electrically connected to a circuit of the peripheral circuit structure PC through the lower contact plugs PCP. The circuit of the peripheral circuit structure PC may include an NMOS transistor, a PMOS transistor, a resistor, a capacitor, and the like as described with reference to FIG. 1. For example, the NMOS transistor may be connected to the peripheral circuit lines PCL through the lower contact plugs PCP.

The lower insulating layer LIL may cover the circuit of the peripheral circuit structure PC, the peripheral circuit lines PCL, and the lower contact plugs PCP. The lower insulating layer LIL may include insulating layers that are stacked as a multi-layer.

The peripheral contact plug CTP may be connected to any one of the peripheral circuit lines PCL while penetrating the lower insulating layer LIL. For example, the peripheral contact plug CTP may penetrate a dummy stack structure DM and may extend into the lower insulating layer LIL while passing through the inside of a source insulating layer SSIL to be connected to the peripheral circuit line PCL. The peripheral circuit line PCL may be a line electrically connected to the NMOS transistor, which constitutes a block select transistor.

The source stack structure SOS may include at least one doped semiconductor layer that is disposed over the lower insulating layer LIL. For example, the source stack structure SOS may include an n-type doped semiconductor layer that is doped with an n-type impurity. Alternatively, the source stack structure SOS may be formed in a stack structure of a p-type doped semiconductor layer that is doped with a p-type impurity and an n-type doped semiconductor layer that is doped with an n-type impurity. The n-type doped semiconductor layer may be used as a source region of a cell string, and the p-type doped semiconductor layer may be used as a well structure.

In an embodiment, as shown in FIG. 3A, the source stack structure SOS may include a first source layer SL1, a channel connection layer SOC, and a second source layer SL2, which are stacked over the peripheral circuit structure PC. The first source layer SL1, the channel connection layer SOC, and the second source layer SL2 may include an n-type doped semiconductor layer. Each of the first source layer SL1, the channel connection layer SOC, and the second source layer SL2 of the source stack structure SOS may be penetrated by the isolation insulating layer SIL and the source insulating layer SSIL.

The source insulating layer SSIL may be disposed above the substrate SUB and may be disposed to be spaced apart from the source stack structure SOS. The source insulating layer SSIL may disposed at the same level as the source stack structure SOS.

The isolation insulating layer SIL may be disposed between the source stack structure SOS and the source insulating layer SSIL. More specifically, the isolation insulating layer SIL may be disposed on a sidewall of the source stack structure SOS. The isolation insulating layer SIL may be penetrated by the source insulating layer SSIL. In other words, the source insulating layer SSIL may include a bottom surface in contact with the lower insulating layer LIL.

The isolation insulating layer SIL and the source insulating layer SSIL may include different materials. In an embodiment, the isolation insulating layer SIL may include an insulating material having a high etch selectivity with respect to a silicon layer when compared to an etch selectivity of the source insulating layer SSIL with respect to the silicon layer. In an embodiment, the isolation insulating layer SIL may include a nitride layer, and the source insulating layer SSIL may include an oxide layer.

A first stack structure ST1 and a second stack structure ST2 may be disposed at a level that is higher than a level at which the isolation insulating layer SIL and the source insulating layer SSIL are disposed. The first stack structure ST1 may be provided as a gate stack structure GST, and the second stack structure ST2 may be provided as a dummy stack structure DM.

Insulating bars IB may be disposed at a boundary between the gate stack structure GST and the dummy stack structure DM. Insulating pillars IP may penetrate the gate stack structure GST.

The gate stack structure GST may include a plurality of interlayer insulating layers ILD and a plurality of conductive layers CP, which are alternately stacked on the source stack structure SOS. Each interlayer insulating layer ILD may extend in the horizontal direction to surround a plurality of vertical structures CPL.

The dummy stack structure DM may include a plurality of dummy interlayer insulating layers DIL and a plurality of sacrificial layers SC, which are alternately stacked on the source insulating layer SSIL. Each dummy interlayer insulating layer DIL and each sacrificial layer SC may extend in the horizontal direction to surround a peripheral contact plug CTP. The plurality of dummy interlayer insulating layers DIL may be disposed at levels that are substantially equal to levels of the plurality of interlayer insulating layers ILD, and the plurality of sacrificial layers SC may be disposed at levels that are substantially equal to levels of the plurality of conductive layers CP.

The peripheral contact plug CTP may penetrate the plurality of dummy interlayer insulating layers DIL and the plurality of sacrificial layers SC of the dummy stack structure DM. The peripheral contact plug CTP may include an upper contact UCT that penetrates the dummy stack structure and a lower contact BCT that penetrates the source insulating layer SSIL. The lower contact BCT may be spaced apart from the source stack structure SOS by the isolation insulating layer SIL in addition to the source insulating layer SSIL.

Each conductive layer CP may be formed of various conductive materials including a doped silicon layer, a metal layer, a metal silicide layer, a barrier layer, and the like and may include two or more kinds of conductive materials. In an embodiment, each conductive layer CP may include tungsten and a titanium nitride layer (TiN) that surrounds a surface of the tungsten. The tungsten may be a low resistance metal and may lower the resistance of the conductive layer CP. The titanium nitride layer (TiN) is a barrier layer and may block the direct contact between the tungsten and the interlayer insulating layer ILD. Each interlayer insulating layer ILD may be formed of an insulating material including an oxide layer and the like. The plurality of dummy interlayer insulating layers DIL may be formed of the same insulating material as the plurality of interlayer insulating layer ILD. The plurality of sacrificial layers SC may be formed of a material that is different from the material of the plurality of interlayer insulating layers ILD. More specifically, the plurality of sacrificial layers SC may be formed of a material having a high etch rate difference with respect to the plurality of interlayer insulating layers ILD. In an embodiment, each sacrificial layer may be formed of a nitride layer.

The plurality of conductive layers CP may be used as source select lines, word lines, and drain select lines. The source select lines may be used as gate electrodes of source select transistors, the word lines may be used as gate electrodes of memory cells, and the drain select lines may be used as gate electrodes of drain select transistors.

Each of the first slit SI1 and the second slit SI2, which are shown in FIG. 2, may be filled with a sidewall insulating layer SWI and a source contact structure SCT. The sidewall insulating layer SWI may extend along a sidewall of a slit (e.g., SI1) corresponding thereto and may be formed on a sidewall of the gate stack structure GST. The source contact structure SCT may be insulated from the plurality of conductive layers CP by the sidewall insulating layer SWI. The source contact structure SCT may extend into the source stack structure SOS and may be in contact with the channel connection layer SCC. The source contact structure SCT may be formed of various conductive materials including a doped silicon layer, a metal layer, a metal silicide layer, a barrier layer, and the like and may include two or more kinds of conductive materials. In an embodiment, the source contact structure SCT may be formed in a stack structure of a doped silicon layer in contact with the channel connection layer SCC and a metal layer that are formed on the doped silicon layer. The doped silicon layer may include an n-type dopant, and the metal layer may be formed of a low resistance metal, such as tungsten so as to lower resistance thereof.

Referring to FIG. 3B, an isolation insulating layer SIL may be formed in a structure that is different from the structure of the isolation insulating layer described with reference to FIG. 3A. Hereinafter, overlapping descriptions of the same components will be omitted.

Referring to FIG. 3B, the isolation insulating layer SIL may include a first part P1 that is disposed between the source stack structure SOS and the source insulating layer SSIL and a second part P2 that is disposed between the source insulating layer SSIL and the lower insulating layer LIL. The lower contact BCT may be connected to the peripheral circuit line PCL while penetrating the source insulating layer SSIL, the second part P2 of the isolation insulating layer SIL, and a portion of the lower insulating layer LIL.

Referring to FIGS. 3A and 3B, each vertical structure CPL may include a channel layer CL and a memory layer ML. The channel layer CL may penetrate the first stack structure ST1, which constitutes the gate stack structure, and the channel layer CL may extend into the source stack structure SOS. The memory layer ML may be interposed between the channel layer CL and the gate stack structure GST and between the channel layer CL and the first source layer SL1 of the source stack structure SOS. The channel layer CL may be used as a channel region of the cell string and may include a semiconductor material, such as silicon. The channel layer CL may be formed in a tubular shape. When the channel layer CL is formed in the tubular shape, the vertical structure CPL may further include a core insulating layer CO and a capping pattern CAP, which are disposed in a central region of the channel layer CL. The capping pattern CAP may include a doped semiconductor layer. The channel layer CL may include a sidewall that is in contact with the channel connection layer SCC, between the first source layer SL1 and the second source layer SL2. The channel connection layer SCC may be connected to a portion of the channel layer CL, which is disposed at a level that is substantially same as the level of the channel connection layer SCC.

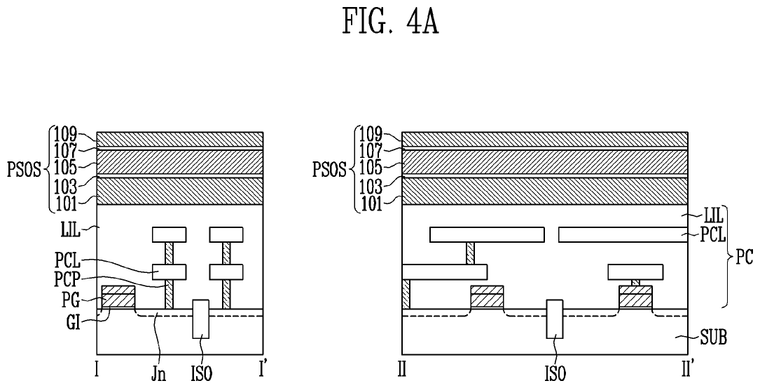

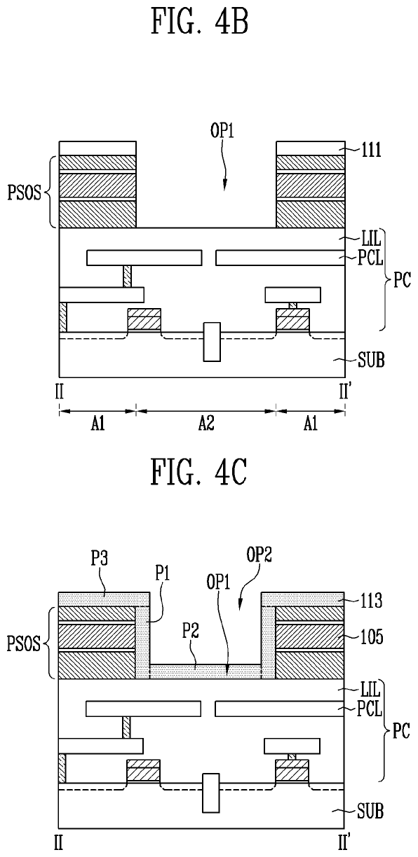

FIGS. 4A to 4C are sectional views illustrating a manufacturing method of a semiconductor memory device in accordance with an embodiment of the present disclosure. More specifically, FIG. 4A is a sectional view illustrating a process of forming a preliminary source stack structure PSOS in the manufacturing method of the semiconductor memory device taken along the lines I-I′ and II-II′, shown in FIG. 2. FIGS. 4B and 4C are sectional views illustrating subsequent processes that are continued after the preliminary source stack structure PSOS and are process sectional views, taken along the line II-II′, shown in FIG. 2.

Referring to FIG. 4A, an isolation layer, defining an active region of a substrate SUB, may be formed inside the substrate SUB. Then, a gate insulating layer GI, peripheral gate electrodes PG, source and drain junctions in, peripheral circuit lines PCL, lower contact plugs PCP, and a lower insulating layer LIL may be formed, which constitute the peripheral circuit structure PC, described with reference to FIG. 3A.

Subsequently, the preliminary source stack structure PSOS may be formed over the lower insulating layer LIL. The preliminary source stack structure PSOS may include a first source layer 101, a source sacrificial layer 105, and a second source layer 109, which are sequentially stacked. The preliminary source stack structure PSOS may further include a first protective layer 103 that is disposed between the first source layer 101 and the source sacrificial layer 105 and may further include a second protective layer 107 that is disposed between the source sacrificial layer 105 and the second source layer 109.

At least one of the first source layer 101 and the second source layer 109 may be formed of a doped semiconductor layer. In an embodiment, the first source layer 101 and the second source layer 109 may be formed of a doped silicon layer. The first source layer 101 and the second source layer 109 may include an n-type impurity. The first protective layer 103 and the second protective layer 107 may be formed of an oxide layer. The source sacrificial layer 105 may be formed of an undoped semiconductor layer. In an embodiment, the source sacrificial layer 105 may be formed of an undoped silicon layer.

Referring to FIG. 4B, a mask pattern 111 may be formed over the preliminary source stack structure PSOS. The mask pattern 111 may be patterned through a photolithography process. Subsequently, the preliminary source stack structure PSOS may be etched through an etching process by using the mask pattern 111 as an etch barrier. Accordingly, a first opening OP1 may be formed to penetrate the preliminary source stack structure PSOS. The first opening OP1 may be formed to expose the lower insulating layer LIL.

The mask pattern 111 may be removed after the first opening OP1 is formed.

Hereinafter, the substrate SUB may be divided into a first region A1 and a second region A2 with respect to the first opening OP1. A partial region of the substrate SUB, which is disposed under the preliminary source stack structure PSOS, may be defined as the first region A1, and a partial region of the substrate SUB, which is disposed under the first opening OP1, may be defined as the second region A2. In other words, a process of forming the first opening OP1 may be performed such that the preliminary source stack structure PSOS remains in regions that overlap with the first region A1 of the substrate SUB while the first opening OP1 overlaps with the second region A2 of the substrate SUB.

Referring to FIG. 4C, a first insulating material 113 may be formed along a surface of the first opening OP1. The first insulating material 113 may include an insulating material having a high etch selectivity with respect to the source sacrificial layer 105 when compared to the etch selectivity of the oxide layer with respect to the source sacrificial layer 105. In an embodiment, the first insulating layer 113 may be formed of a nitride layer. The first insulating material 113 may include a first part P1 that is formed on a sidewall of the preliminary source stack structure PSOS, a second part P2 that is formed on a bottom surface of the first opening OP1, and a third part P3 that is formed to cover the preliminary source stack structure PSOS.

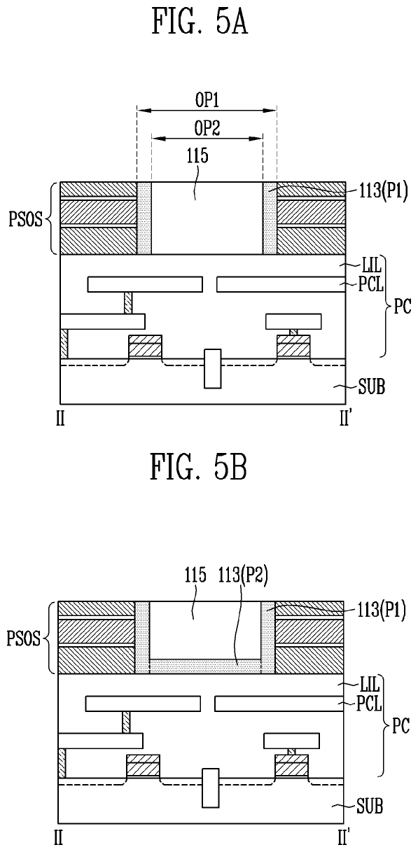

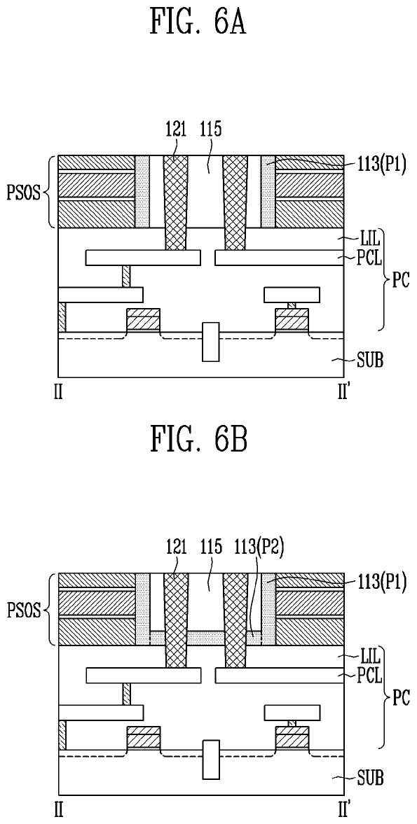

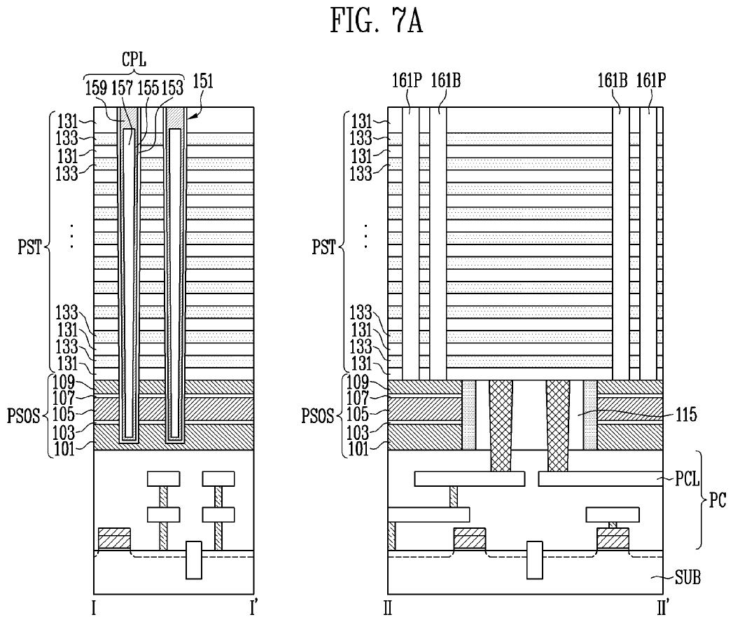

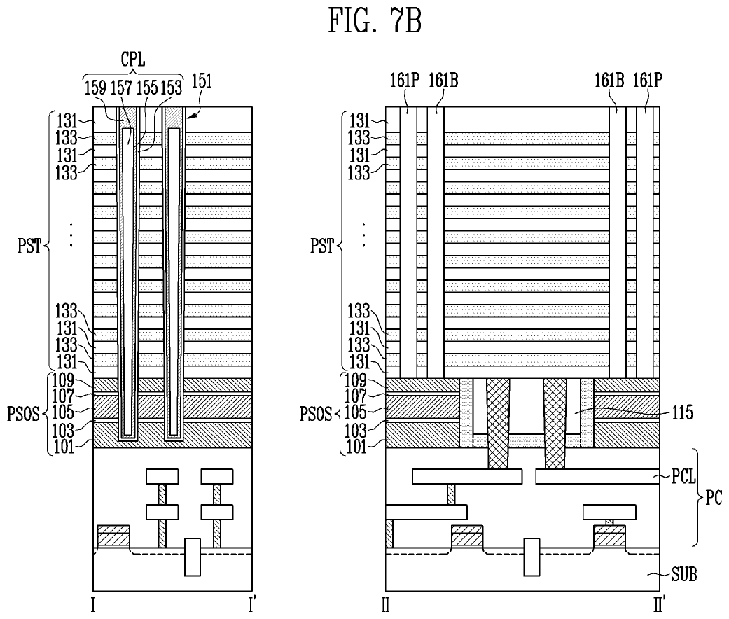

FIGS. 5A to 11B are sectional views illustrating a manufacturing method of a semiconductor memory device in accordance with an embodiment of the present disclosure. More specifically, FIGS. 5A to 6B are process sectional views, taken along the line II-II′, shown in FIG. 2, and FIGS. 7A to 11B are process sectional views, taken along the lines I-I′ and II-II′, shown in FIG. 2.

FIGS. 5A, 6A, 7A, 8A, 9A, 10A, and 11A are process sectional views illustrating a manufacturing method of the semiconductor memory device in accordance with an embodiment of the present disclosure. FIGS. 5B, 6B, 7B, 8B, 9B, 10B, and 11B are process sectional views illustrating a manufacturing method of the semiconductor memory device in accordance with another embodiment of the present disclosure.

FIGS. 5A and 5B are sectional views illustrating processes of forming second insulating materials in accordance with embodiments of the present disclosure.

Referring to FIG. 5A, the second part P2 and the third part P3 of the first insulating material 113, described with reference to FIG. 4C, may be removed. An etch-back process or planarization and etch-back processes may be performed such that the second part P2 and the third part P3 of the first insulating material 113 are removed. Accordingly, the first part P1 of first insulating material 113 may remain, and the lower insulating layer LIL may be exposed through the bottom surface of the first opening OP1. Hereinafter, an internal space of the first opening OP1, which is exposed through the removal of the second part P2 and the third part P3 of the first insulating material 113, may be defined as a second opening OP2.

Subsequently, a second insulating material 115 may be formed inside the second opening OP2. The second insulating material 115 may be formed of an oxide layer. A surface of the second insulating material 115 may be planarized such that a top surface of the preliminary source stack structure PSOS is exposed. In order to planarize the second insulating material 115, a Chemical Mechanical Polishing (CMP) process may be used.

Referring to FIG. 5B, a second insulating material 115 may be formed over the first insulating material 113, described with reference to FIG. 4C. The second insulating material 115 may be formed of an oxide layer. Surfaces of the first insulating material 113 and the second insulating material 115 may be planarized such that a top surface of the preliminary source stack structure PSOS is exposed. In order to the first insulating material 113 and the second insulating material 115, a Chemical Mechanical Polishing (CMP) process may be used. Accordingly, the first part P1 and the second part P2 of the first insulating material 113 may remain.

FIGS. 6A and 6B are sectional views illustrating processes of forming lower contacts in accordance with embodiments of the present disclosure.

Referring to FIG. 6A a lower contact 121 may be formed to penetrate the second insulating material 115, provided through the process that is described with reference to FIG. 5A.

Referring to FIG. 6B, a lower contact 121 may be formed to penetrate the second insulating material 115 and the second part P2 of the first insulating material 113, which are provided through the process that is described with reference to FIG. 5B.

Referring to FIGS. 6A and 6B, the lower contact 121 may penetrate a partial region of the lower insulating layer LIL between the second insulating material 115 and the peripheral circuit line PCL of the peripheral circuit structure PC to be connected to the peripheral circuit line PCL. The lower contact 121 may be spaced apart from the preliminary source stack structure PSOS. In accordance with embodiments of the present disclosure, the lower contact 121 may be spaced apart from the preliminary source stack structure PSOS, the first part P1 of the first insulating material 113 and the second insulating material 115 being interposed between the lower contact 121 and the preliminary source stack structure PSOS.

FIG. 7A is a sectional view illustrating a subsequent process with respect to the structure shown in FIG. 6A, and FIG. 7B is a sectional view illustrating a subsequent process with respect to the structure shown in FIG. 6B.

FIGS. 7A and 7B, a preliminary stack structure PST including first material layers 131 and second material layers 133 may be formed over the preliminary source stack structure PSOS. The alternately stacked number of the first material layers 131 and the second material layers 133 may be variously changed.

The first material layers 131 may be formed of an insulating material for interlayer insulating layers, and the second material layers 133 may be formed of an insulating material for sacrificial layers. The second material layers 133 may be formed of a material that is different from the material of the first material layers 131. More specifically, the second material layers 133 may be formed of a material that can be etched while minimizing etching of the first material layers 131 in a process of selectively etching the second material layers 133. In other words, the second material layers 133 may be formed of a material having a high etch rate difference with respect to the first material layers 131. In an embodiment, the first material layers 131 may be formed of an oxide layer, such as a silicon oxide layer (SiO₂), and the second material layers 133 may be formed of a nitride layer, such as a silicon nitride layer (SiN).

Subsequently, support structures 161P and 1618 that penetrate the preliminary stack structure PST may be formed. In addition, a vertical structure CPL that penetrates the preliminary stack structure PST may be formed. The vertical structure CPL may extend into the first source layer 101 while further penetrating the second source layer 109, the second protective layer 107, the source sacrificial layer 105, and the first protective layer 103.

The support structures 161P and 1618 may penetrate the preliminary stack structure PST that is adjacent to the second insulating layer 115 as described with reference to FIG. 3A. The support structures 161P and 1618 may include insulating pillars 161P and insulating bars 1618 as described with reference to FIG. 3A. The structure and arrangement of the support structures 161P and 1618 may be variously changed.

Each of the vertical structures CPL may be formed inside a channel hole 151 that penetrates the preliminary stack structure PST. The channel hole 151 may extend into the first source layer 101 while further penetrating the second source layer 109, the second protective layer 107, the source sacrificial layer 105, and the first protective layer 103. The process of forming the vertical structures CPL may include a process of performing an etching process for forming the channel hole 151, a process of forming a memory layer 153 on a surface of the channel hole 151, and a process of forming a channel layer 155 on the memory layer 153.

The memory layer 153 may include a blocking insulating layer, a data storage layer, and a tunnel insulating layer. The channel layer 155 may be formed of a semiconductor layer. In an embodiment, the channel layer 155 may be formed to completely fill a central region of the channel hole 151. In another embodiment, the channel layer 155 may be conformally formed on the memory layer 153, and the central region of the channel hole 151 might not be completely filled with the channel layer 155. A core insulating layer 157 and a capping pattern 159, which fill the central region of the channel hole 151, may be formed on the channel layer 155. The capping pattern 159 may fill the central region of the channel hole 151 on the core insulating layer 157. The capping pattern 159 may be formed of a doped semiconductor layer.

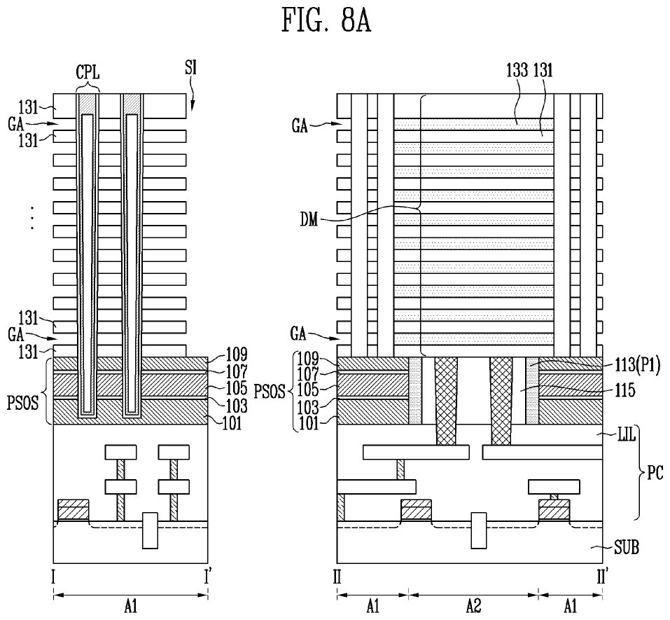

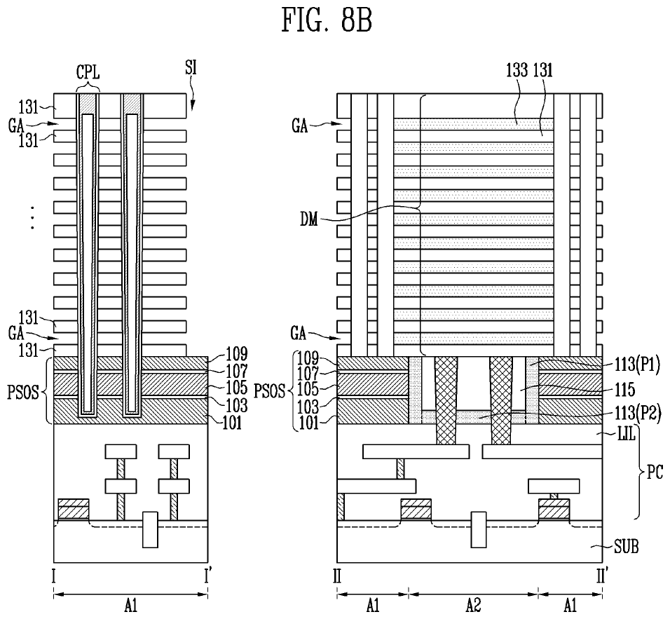

FIG. 8A is a sectional view illustrating a subsequent process with respect to the structure shown in FIG. 7A, and FIG. 8B is a sectional view illustrating a subsequent process with respect to the structure shown in FIG. 7B.

Referring to FIGS. 8A and 8B, a slit SI may be formed, which penetrates the preliminary stack structure PST, shown in FIGS. 7A and 7B. A layout of the slit SI may be the same as the first slit SI1 that is described with reference to FIG. 2. The second slit SI2, described with reference to FIG. 2, may be simultaneously provided with the first slit SI1 through a process of forming the slit SI.

The slit SI may overlap with the first region A1 of the substrate SUB. That is, the slit SI may overlap with the preliminary source stack structure PSOS, and therefore, the preliminary source stack structure PSOS may be used as an etch stop layer in an etching process for forming the slit SI. In particular, the second source layer 109 of the preliminary source stack structure PSOS may be used as an etch stop layer. Accordingly, a phenomenon in which the peripheral circuit structure PC including the peripheral circuit line PCL is damaged due to the influence of the etching process for the slit SI that is formed to a deep depth may be prevented or mitigated.

Subsequently, the second material layers 133 of the preliminary stack structure PST, shown in FIGS. 7A and 7B, may be selectively removed through the slit SI. Regions in which the second material layers are removed are defined as gate regions GA. The gate regions GA may be formed to expose the vertical structures CPL.

An etching process for forming the gate regions GA may be controlled such that the first material layers 131 and the second material layers 133 of the preliminary stack structure PST, which overlap with the first insulating material 113 and the second insulating material 115, may remain as a dummy stack structure DM. In other words, the preliminary stack structure PST may remain as the dummy stack structure DM that overlaps with the second region A2 of the substrate SUB.

The support structures 161P and 161B may provide support such that the first material layers 131 might not collapse but may be maintained even when the gate regions GA are formed. During the etching process for forming the gate regions GA, the support structures 161P and 161B may block an etching material introduced from the slit SI from being introduced toward a region overlapping with the first insulating material 113 and the second insulating material 115. Accordingly, the second material layers 133 of the dummy stack structure DM might not be removed but may remain.

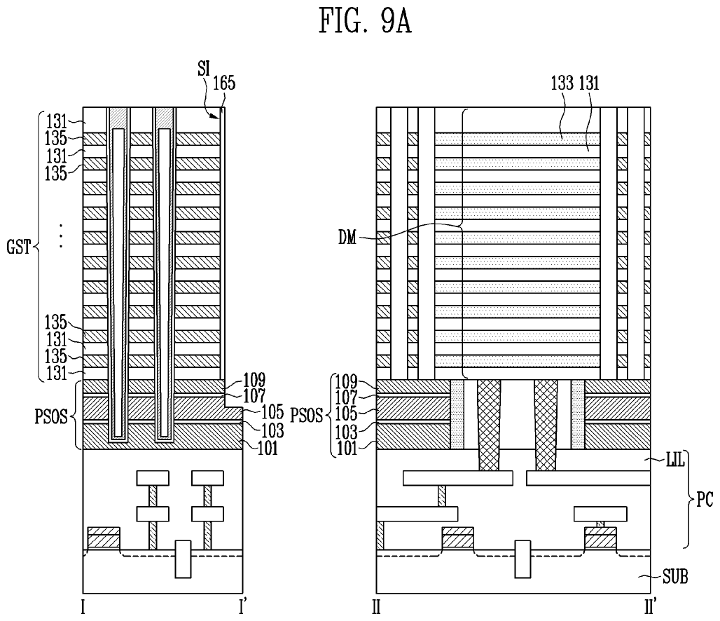

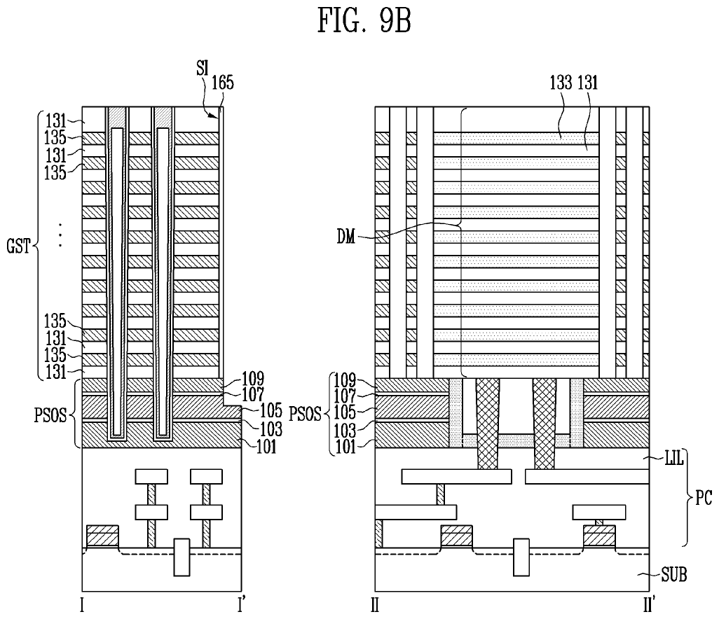

FIG. 9A is a sectional view illustrating a subsequent process with respect to the structure shown in FIG. 8A, and FIG. 9B is a sectional view illustrating a subsequent process with respect to the structure shown in FIG. 8B.

Referring to FIGS. 9A and 9B, third material layers 135 may be respectively formed inside the gate regions GA, shown in FIGS. 8A and 8B.

Each of the third material layers 135 may include at least one of a doped silicon layer, a metal silicide layer, and a metal layer. Each of the third material layers 135 may include a metal for low resistance wiring. In an embodiment, each of the third material layers 135 may include a low resistance metal, such as tungsten or molybdenum. Each of the third material layers 135 may further include a barrier layer, such as a titanium nitride layer, a tungsten nitride layer, or a tantalum nitride layer.

Through the above-described process, a gate stack structure GST including the first material layers 131 and the third material layers 135, which are alternately disposed, may be formed.

Subsequently, a sidewall insulating layer 165 may be formed on a sidewall of the slit SI. Then, the source sacrificial layer 105 may be exposed by etching the second source layer 109 and the second protective layer 107, which are exposed through the slit SI.

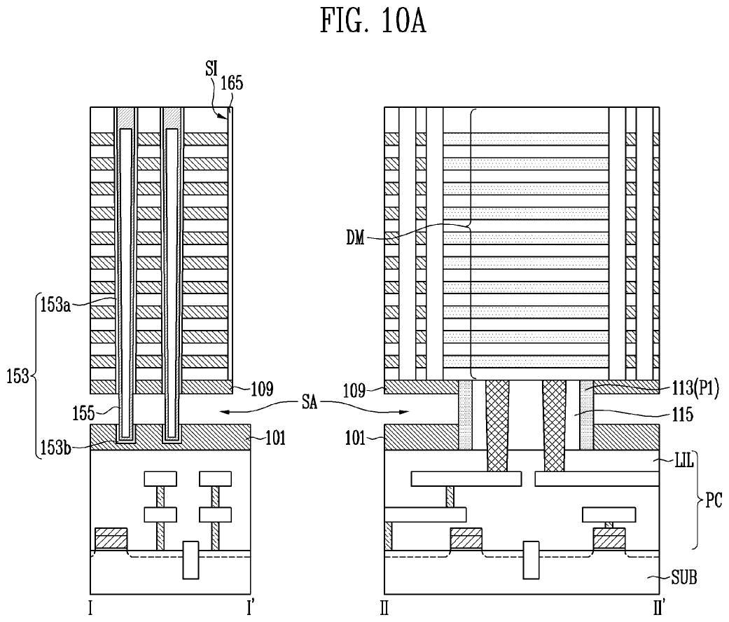

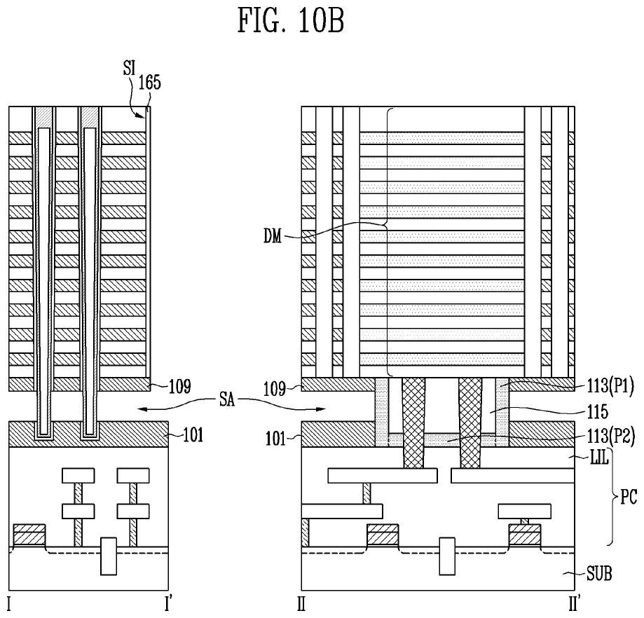

FIG. 10A is a sectional view illustrating a subsequent process with respect to the structure shown in FIG. 9A, and FIG. 10B is a sectional view illustrating a subsequent process with respect to the structure shown in FIG. 9B.

FIGS. 10A and 10B, a source region SA may be defined by removing the source sacrificial layer 105, shown in FIGS. 9A and 9B. The source region SA may be an opening region that is defined by the first source layer 101 and the second source layer 109.

Subsequently, the memory layer 153 may be isolated into a first memory layer 153a and a second memory layer 153b by etching the memory layer 153 that is exposed through the source region SA. A portion of a sidewall of the channel layer 155 may be exposed between the first memory layer 153a and the second memory layer 153b. During the process of etching the memory layer 153, the first protective layer 103 and the second protective layer 107, which are shown in FIGS. 9A and 9B, may be removed. Accordingly, a bottom surface of the second source layer 109 and a top surface of the first source layer 101, which face the source region SA, may be exposed.

The first insulating material 113 may be formed of a material that is different from the material of the second insulating material 115. More specifically, in a process of selectively removing the source sacrificial layer 105 shown in FIGS. 9A and 9B, the first insulating material 113 may include a material having a high etch selectivity with respect to the source sacrificial layer 105, as compared with the second insulating material 115. Accordingly, while the source sacrificial layer 105, shown in FIGS. 9A and 9B, is being selectively removed, the first insulating material 113 may protect the second insulating material 115. In an embodiment, the first insulating material 113 may be formed of a nitride layer, and the second insulating material 115 may be formed of an oxide layer.

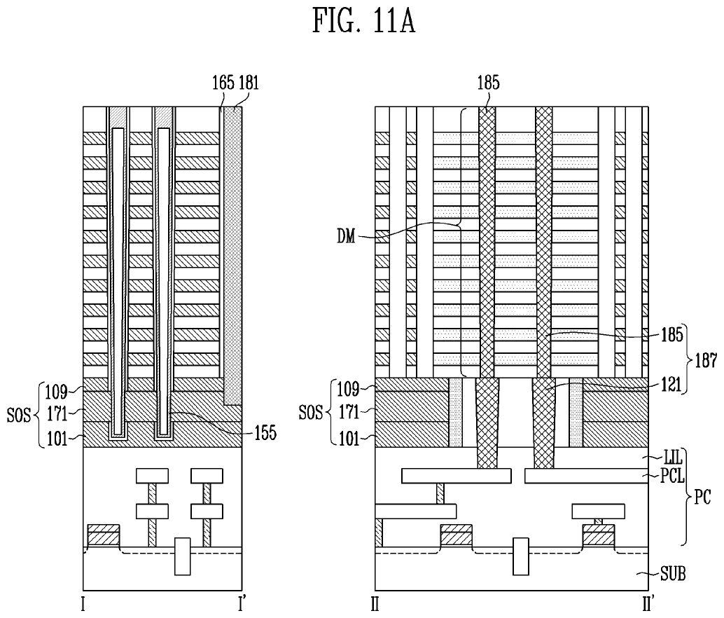

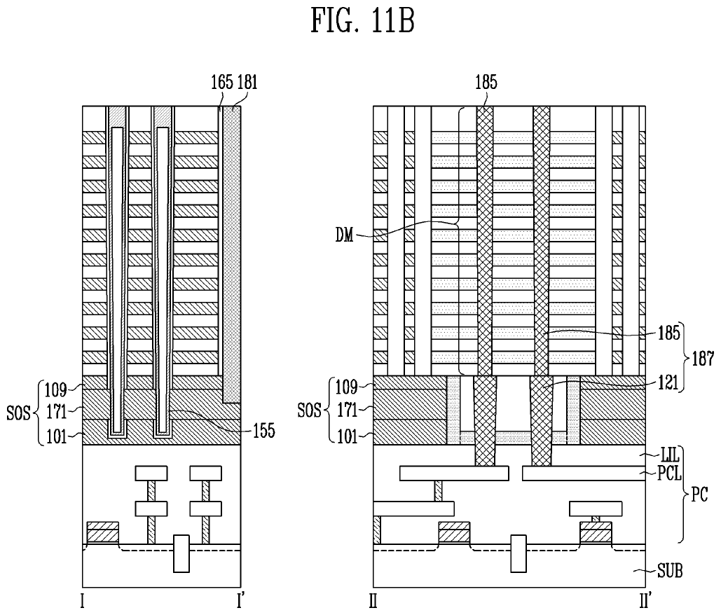

FIG. 11A is a sectional view illustrating a subsequent process with respect to the structure shown in FIG. 10A, and FIG. 11B is a sectional view illustrating a subsequent process with respect to the structure shown in FIG. 10B.

Referring to FIGS. 11A and 11B, a channel connection layer 171 may be formed inside the source region SA shown in FIGS. 10A and 10B. The channel connection layer 171 may be in contact with the channel layer 155, the first source layer 101, and the second source layer 109. The first source layer 101, the channel connection layer 171, and the second source layer 109 may form a source stack structure SOS. The channel connection layer 171 may be formed through a chemical vapor deposition process or a growth process by using, as a seed layer, the channel layer 155, the first source layer 101, and the second source layer 109.

Subsequently, a source contact structure 181 may be formed, which is filled inside the slit SI. The source contact structure 181 may be formed on the sidewall insulating layer 165 and may be in contact with the channel connection layer 171.

Subsequently, an upper contact 185 may be formed, which penetrates the dummy stack structure DM. The upper contact 185 may be in contact with the lower contact 121. The upper contact 185 and the lower contact 121 may form a peripheral contact plug 187. The peripheral contact plug 187 may be connected to the peripheral circuit line PCL of the peripheral circuit structure PC. The first material layers 131, shown in FIGS. 9A and 9B, may remain as dummy interlayer insulating layer of the dummy stack structure DM, and the second material layers 133, shown in FIGS. 9A and 9B, may remain as sacrificial layers of the dummy stack structure DM. The first material layers 131 and the second material layers 133, which are shown in FIGS. 9A and 9B, are formed of an insulating material having an etch selectivity, and therefore, an etching process for defining a space in which the peripheral contact plug 187 is disposed may be performed by using insulating layers as a target without blocking any conductive material or any semiconductor layer.

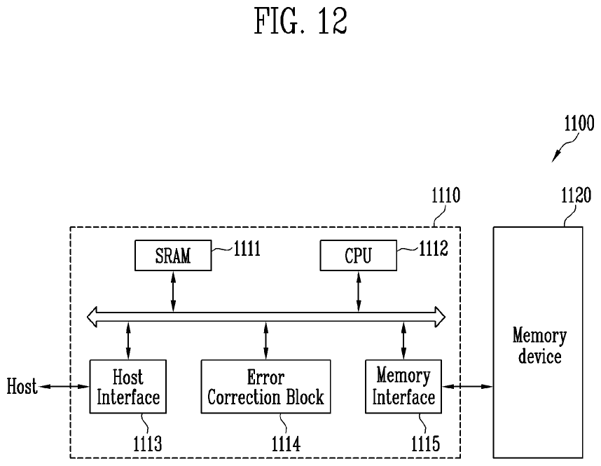

FIG. 12 is a block diagram illustrating a configuration of a memory system in accordance with an embodiment of the present disclosure.

Referring to FIG. 12, the memory system 1100 may include a memory device 1120 and a memory controller 1110.

The memory device 1120 may be a multi-chip package configured with a plurality of flash memory chips. The memory device 1120 may be a nonvolatile memory. Also, the memory device 1120 may have the structure described above with reference to FIGS. 1 to 3B and may be manufactured according to the manufacturing method described above with reference to FIGS. 4A to 11B. In an embodiment, the memory device 1120 may include: a substrate, a source stack structure and a source insulating layer, which are disposed over the substrate to be spaced apart from each other; an isolation insulating layer disposed between the source stack structure and the source insulating layer; a first stack structure on the source stack structure; a second stack structure disposed over the source insulating layer; a vertical structure penetrating the first stack structure and a portion of the source stack structure; and a low contact penetrating the source insulating layer.

The memory controller 1110 may control the memory device 1120 and may include a Static Random Access Memory (SRAM) 1111, a Central Processing Unit (CPU) 1112, a host interface 1113, an error correction block 1114, and a memory interface 1115. The SRAM 1111 may be used as an operation memory of the CPU 1112, the CPU 1112 performs overall control operations for data exchange of the memory controller 1110, and the host interface 1113 may include a data exchange protocol for a host that is connected with the memory system 1100. The error correction block 1114 may detect an error included in a data read from the memory device 1120 and may correct the detected error. The memory interface 1115 may interface with the memory device 1120. The memory controller 1110 may further include a Read Only Memory (ROM) for storing code data for interfacing with the host, and the like.

The memory system 1100, configured as described above, may be a memory card or a Solid State Disk (SSD) in which the memory device 1120 is combined with the controller 1110. For example, when the memory system 1100 is an SSD, the memory controller 1100 may communicated with the outside (e.g., the host) through one of various interface protocols, such as a Universal Serial Bus (USB) protocol, a Multi-Media Card (MMC) protocol, a Peripheral Component Interconnection (PCI) protocol, a PCI-Express (PCI-E) protocol, an Advanced Technology Attachment (ATA) protocol, a Serial-ATA (SATA) protocol, a Parallel-ATA (PATA) protocol, a Small Computer System Interface (SCSI) protocol, an Enhanced Small Disk Interface (ESDI) protocol, and an Integrated Drive Electronics (IDE) protocol.

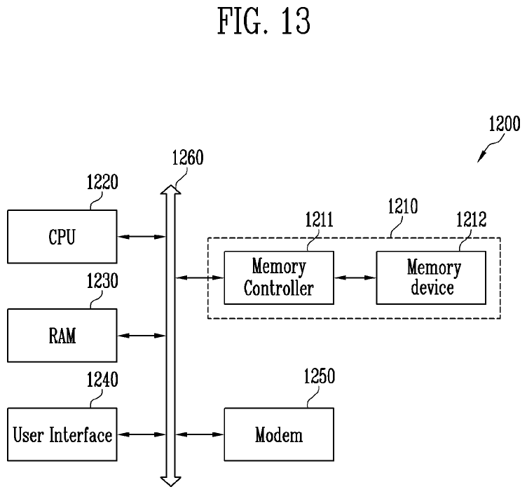

FIG. 13 is a block diagram illustrating a configuration of a computing system in accordance with an embodiment of the present disclosure.

Referring to FIG. 13, the computing system 1200 may include a CPU 1220, a random access memory (RAM) 1230, a user interface 1240, a modem 1250, and a memory system 1210, which are electrically connected to a system bus 1260. When the computing system 1200 is a mobile device, a battery for supplying an operation voltage to the computing system 1200 may be further included, and an application chip set, an image processor, a mobile DRAM, and the like may be further included.

The memory system 1210 may be configured with a memory device 1212 and a memory controller 1211.

The memory device 1212 may have the same configuration as the memory device 1120 described above with reference to FIG. 12.

The memory controller 1211 may have the same configuration as the memory controller 1110 that is described above with reference to FIG. 12.

In accordance with the present disclosure, an isolation insulating layer is formed over sidewall of a source stack structure, thereby improving operational reliability.

What is claimed is:

1. A semiconductor memory device comprising:
a substrate;
a source stack structure and a source insulating layer disposed over the substrate to be spaced apart from each other;
an isolation insulating layer disposed between the source stack structure and the source insulating layer;
a first stack structure disposed over the source stack structure;
a second stack structure disposed over the source insulating layer;
a vertical structure penetrating the first stack structure and a portion of the source stack structure; and
a lower contact penetrating the source insulating layer.

2. The semiconductor memory device of claim 1, wherein the source stack structure and the source insulating layer are disposed at the same level.

3. The semiconductor memory device of claim 1, wherein the isolation insulating layer includes a material that is different from that of the source insulating layer.

4. The semiconductor memory device of claim 3, wherein the isolation insulating layer includes a nitride layer.

5. The semiconductor memory device of claim 1, further comprising a peripheral circuit structure disposed between the substrate and the source stack structure and between the substrate and the source insulating layer,
wherein the lower contact is connected to the peripheral circuit structure.

6. The semiconductor memory device of claim 5, wherein the isolation insulating layer includes:
a first part disposed between the source stack structure and the source insulating layer; and
a second part disposed between the source insulating layer and the peripheral circuit structure.

7. The semiconductor memory device of claim 6, wherein the second part of the isolation insulating layer is penetrated by the lower contact.

8. The semiconductor memory device of claim 1, further comprising an upper contact that penetrates the second stack structure and connects to the lower contact.

9. The semiconductor memory device of claim 1, wherein the lower contact is spaced apart from the source stack structure.

10. The semiconductor memory device of claim 1, wherein the isolation insulating layer is penetrated by the source insulating layer.

11. The semiconductor memory device of claim 1, wherein the source stack structure includes a first source layer and a second source layer, and
wherein the vertical structure penetrates the first source layer and a portion of the second source layer.

12. The semiconductor memory device of claim 11, wherein the source stack structure further includes a channel connection layer between the first source layer and the second source layer,
wherein the vertical structure includes a channel layer and a memory layer, and
wherein the channel connection layer is connected to a portion of the channel layer, which is disposed at the same level as the channel connection layer.

13. A semiconductor memory device comprising:
a source stack structure and a source insulating layer disposed over a peripheral circuit to be spaced apart from each other;
an isolation insulating layer disposed between the source insulating layer and the source stack structure;
a first stack structure including a plurality of interlayer insulating layers and a plurality of conductive layers over the source stack structure;
a slit partitioning the first stack structure, the slit extending into the source stack structure; and
a lower contact penetrating the source insulating layer.

14. The semiconductor memory device of claim 13, wherein the isolation insulating layer extends between the peripheral circuit structure and the source insulating layer.

15. The semiconductor memory device of claim 13, wherein the isolation insulating layer is disposed on a sidewall of the source stack structure.

16. The semiconductor memory device of claim 13, further comprising a second stack structure including a plurality of dummy interlayer insulating layers and a plurality of sacrificial layers, disposed over the source insulating layer.

17. A method of manufacturing a semiconductor memory device, the method comprising:
forming a peripheral circuit structure on a substrate that includes a first region and a second region;
forming a preliminary source stack structure over the peripheral circuit structure;
forming an opening that penetrates the preliminary source stack structure, the opening overlapping with the second region of the substrate;
forming a first insulating material along a sidewall of the opening;
forming a second insulating material inside the opening;
forming a lower contact that penetrates the second insulating material;
forming a preliminary stack structure in which first material layers and second material layers are alternately stacked over the preliminary source stack structure;
forming a vertical structure penetrating the preliminary stack structure and a portion of the preliminary source stack structure, the vertical structure overlapping with the first region of the substrate; and
forming an upper contact that penetrates the preliminary stack structure and connects to the lower contact, the upper contact overlapping with the second region of the substrate.

18. The method of claim 17, wherein the first insulating material includes:
a first part formed on a sidewall of the preliminary source stack structure;
a second part formed on a bottom surface of the opening; and
a third part formed to cover the preliminary source stack structure.

19. The method of claim 18, further comprising removing the second part and the third part of the first insulating material,
wherein the second insulating material is formed on the first part of the first insulating material.

20. The method of claim 18, further comprising planarizing the first insulating material and the second insulating material such that the third part of the first insulating material is removed.

21. The method of claim 20, wherein the lower contact penetrates the second part of the first insulating material.

22. The method of claim 17, further comprising:
forming a slit that penetrates the preliminary stack structure to overlap with the first region; and
forming a gate stack structure by replacing the second material layers with third material layers through the slit,
wherein the first material layers and the second material layers remain to overlap with the second region.

23. The method of claim 22, wherein the preliminary source stack structure includes a first source layer and a source sacrificial layer, which are stacked over the substrate,
wherein the vertical structure includes a channel layer and a memory layer, and
wherein the method further comprises replacing a portion of the memory layer, which is surrounded by the source sacrificial layer, and the source sacrificial layer, with a channel connection layer.

24. The method of claim 23, wherein the first insulating material has a high etch selectivity with respect to the source sacrificial layer when compared to an etch selectivity of the second insulating material with respect to the source sacrificial layer.

25. A method of manufacturing a semiconductor memory device, the method comprising:
forming a preliminary source stack structure over a peripheral circuit structure, the preliminary source stack structure including a first source layer and a source sacrificial layer;
forming an opening that penetrates the preliminary source stack structure;
forming a first insulating material along a sidewall of the opening;
forming a second insulating material inside the opening, which is opened by the first insulating material;
forming a lower contact that penetrates the second insulating material;
forming a preliminary stack structure in which first material layers and second material layers are alternately stacked over the preliminary source stack structure;
forming a slit that penetrates the preliminary stack structure; and
replacing the source sacrificial layer with a channel connection layer through the slit.

26. The method of claim 25, wherein the first insulating material and the second insulating material are stacked inside the opening, and
wherein the lower contact penetrates the first insulating material and the second insulating material.
